(19) United States
(12) Patent Application Publication
(10) Pub. No.: US 2022/0114310 A1
(43) Pub. Date: Apr. 14, 2022

(54) INITIATING A DIGITAL TWIN BASED ON COGNITIVE LOCATION AND ENVIRONMENTAL IMPACT

(71) Applicant: International Business Machines Corporation, Armonk, NY (US)

(72) Inventors: Joseph G. Berti, Highlands Ranch, CO (US); Lisa Seacat DeLuca, Baltimore, MD (US)

(21) Appl. No.: 17/067,830

(22) Filed: Oct. 12, 2020

(51) Int. Cl. G06F 30/27; G06N 20/00

(52) U.S. Cl. CPC G06F 30/27; G06N 20/00

(57) ABSTRACT

Technology for setting a policy for handling a computer-tracked physical asset (for example, a physical asset with a corresponding digital twin) based on policy(ies) for other computer-tracked physical assets that are subject to similar relevant environmental condition(s). Some embodiments use machine learning to refine the relationship between relevant environmental condition(s) and the choice of policy for the physical asset. Some possible types of policies are maintenance action policies and/or spare parts inventory policies.

### BACKGROUND

The present invention relates generally to the field of digital twins, which are a type of machine readable data sets that can be used in managing various kinds of physical assets, like vehicles, bridges, buildings, utility poles, fire hydrants, flood walls, emergency phones, tended gardens, lawns, pumps, large scale electrical components (for example, transformers, power towers), HVAC (heating, ventilation and air conditioning) components (for example, ductwork), land, facilities, infrastructure, major manufacturing equipment, and so on.

The Wikipedia entry for “digital twin” (as of 22 Feb. 2020) states as follows: “A digital twin is a digital replica of a living or non-living physical entity. Digital twin refers to a digital replica of potential and actual physical assets (physical twin), processes, people, places, systems and devices that can be used for various purposes. The digital representation provides both the elements and the dynamics of how an Internet of things device operates and lives throughout its life cycle. Definitions of digital twin technology used in prior research emphasize two important characteristics. Firstly, each definition emphasizes the connection between the physical model and the corresponding virtual model or virtual counterpart. Secondly, this connection is established by generating real time data using sensors. The concept of the digital twin can be compared to other concepts such as cross-reality environments or co-spaces and mirror models, which aim to, by and large, synchronize part of the physical world (e.g., an object or place) with its cyber representation (which can be an abstraction of some aspects of the physical world) . . . . In various industrial sectors, twins are being used to optimize the operation and maintenance of physical assets, systems and manufacturing processes. They are a formative technology for the Industrial Internet of things, where physical objects can live and interact with other machines and people virtually. In the context of the Internet of things, they are also referred to as ‘cyberobjects’, or ‘digital avatars’. The digital twin is also a component of cyber-physical systems.” (footnotes omitted)

### SUMMARY

According to a further aspect of the present invention, there is a method, computer program product and/or system that performs the following operations (not necessarily in the following order): (i) receiving a plurality of existing physical asset profile data sets (PAPDSs), with each existing PAPDS including information indicative of the operating environment in which the existing digital twin is operating; (ii) receiving a request to make a first new PAPDS corresponding to a first physical asset, with the request including information indicative of an operating environment in which the first physical asset is planned to be operated; and (iii) determining a suggested base PAPDS from the plurality of PAPDSs based upon between the following: (a) the operating environments of the suggested base digital twin, and (b) the operating environment indicated in the request.

According to a further aspect of the present invention, there is a method, computer program product and/or system that performs the following operations (not necessarily in the following order): (i) receiving a plurality of physical asset data sets for respectively corresponding physical assets having a common asset type, with each given physical asset data set including information indicative of: (a) identity of the respectively corresponding physical asset, (b) location of the respectively corresponding physical asset, and (c) a first environment-related policy that controls a first environment-related aspect of handling of the respectively corresponding physical asset; (ii) receiving a new physical asset request including information indicative of (a) identity of a new physical asset, and (b) location of the new physical asset; (iii) determining a set of relevant environmental condition(s) that are relevant to selection of first-environment related policy for the plurality of first physical assets of the first asset type; (iv) for each given physical asset data set of the plurality of physical asset data sets, determining relevant environmental condition value(s), corresponding to the set of relevant environmental condition(s), under which the physical asset corresponding to the given physical asset data set operates; (v) for the new physical asset, determining relevant environmental condition value(s), corresponding to the set of relevant environmental condition(s), under which the new physical asset operates; and (vi) creating a new physical asset data set corresponding to the new physical asset, with the creation of the new physical asset data set including: (a) selecting a selected first environment-related policy to control the first environment-related aspect of handling of the new physical asset based, at least in part upon: (I) the relevant environmental condition value(s) corresponding to the plurality of physical asset data sets, and (II) the relevant environmental condition value(s) corresponding to the new physical assets, and (b) adding the selected first environment-related policy to the new physical asset data set.

### BRIEF DESCRIPTION OF THE DRAWINGS

FIG. 1 is a block diagram view of a first embodiment of a system according to the present invention;

FIG. 2 is a flowchart showing a first embodiment method performed, at least in part, by the first embodiment system;

FIG. 3 is a block diagram showing a machine logic (for example, software) portion of the first embodiment system;

FIG. 4 is a screenshot view generated by the first embodiment system;

FIG. 5A is a block diagram view of a second embodiment of a system according to the present invention at a first point in time; and

FIG. 5B is a block diagram view of the second embodiment at a second point in time.

### DETAILED DESCRIPTION

Some embodiments of the present invention are directed to setting a policy for handling a computer-tracked physical asset (for example, a physical asset with a corresponding digital twin) based on policy(ies) for other computer-tracked physical assets that are subject to similar relevant environmental condition(s). Some embodiments use machine learning to refine the relationship between relevant environmental condition(s) and the choice of policy for the physical asset. Some possible types of policies are maintenance action policies and/or spare parts inventory policies. This Detailed Description section is divided into the following subsections: (i) The Hardware and Software Environment; (ii) Example Embodiment; (iii) Further Comments and/or Embodiments; and (iv) Definitions.

### I. The Hardware and Software Environment

The present invention may be a system, a method, and/or a computer program product. The computer program product may include a computer readable storage medium (or media) having computer readable program instructions thereon for causing a processor to carry out aspects of the present invention.

The present invention may be a system, a method, and/or a computer program product at any possible technical detail level of integration. The computer program product may include a computer readable storage medium (or media) having computer readable program instructions thereon for causing a processor to carry out aspects of the present invention. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (for example, light pulses passing through a fiber-optic cable), or electrical signals transmitted through a wire.

A “storage device” is hereby defined to be anything made or adapted to store computer code in a manner so that the computer code can be accessed by a computer processor. A storage device typically includes a storage medium, which is the material in, or on, which the data of the computer code is stored. A single “storage device” may have: (i) multiple discrete portions that are spaced apart, or distributed (for example, a set of six solid state storage devices respectively located in six laptop computers that collectively store a single computer program); and/or (ii) may use multiple storage media (for example, a set of computer code that is partially stored in as magnetic domains in a computer's non-volatile storage and partially stored in a set of semiconductor switches in the computer's volatile memory). The term “storage medium” should be construed to cover situations where multiple different types of storage media are used.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

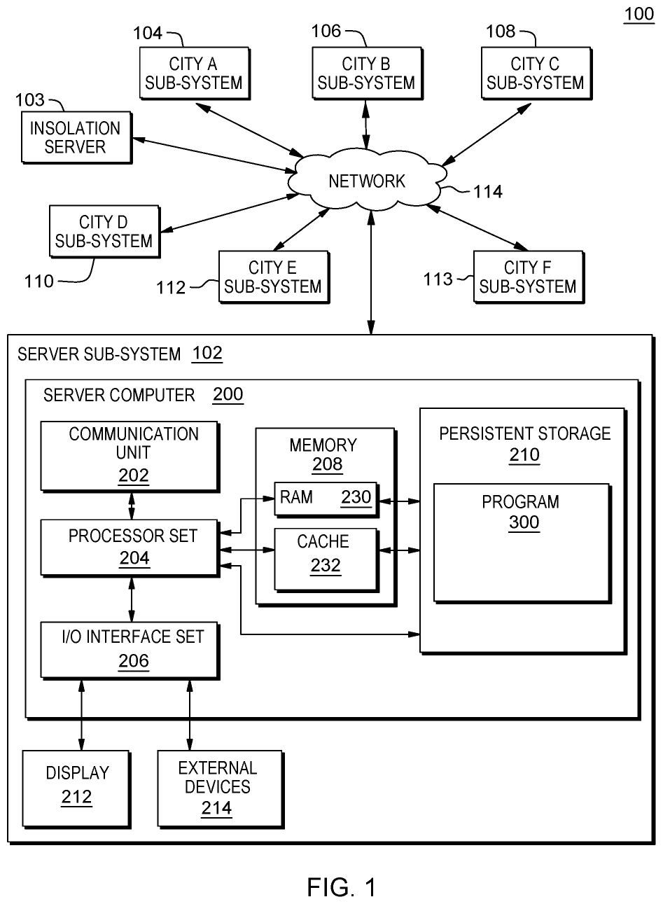

As shown in FIG. 1, networked computers system 100 is an embodiment of a hardware and software environment for use with various embodiments of the present invention. Networked computers system 100 includes: server subsystem 102 (sometimes herein referred to, more simply, as subsystem 102); isolation server 103; city A subsystem 104; city B subsystem 106; city C subsystem 108; city D subsystem 110; city E subsystem 112; city F subsystem 113; and communication network 114. Server subsystem 102 includes: server computer 200; communication unit 202; processor set 204; input/output (I/O) interface set 206; memory 208; persistent storage 210; display 212; external device(s) 214; random access memory (RAM) 230; cache 232; and program 300. In this example, the city subsystems 104, 106, 108, 110, 112, 113 are respectively located in six (6) different cities located in the United States.

Subsystem 102 may be a laptop computer, tablet computer, netbook computer, personal computer (PC), a desktop computer, a personal digital assistant (PDA), a smart phone, or any other type of computer (see definition of “computer” in Definitions section, below). Program 300 is a collection of machine readable instructions and/or data that is used to create, manage and control certain software functions that will be discussed in detail, below, in the Example Embodiment subsection of this Detailed Description section.

Subsystem 102 is capable of communicating with other computer subsystems via communication network 114. Network 114 can be, for example, a local area network (LAN), a wide area network (WAN) such as the Internet, or a combination of the two, and can include wired, wireless, or fiber optic connections. In general, network 114 can be any combination of connections and protocols that will support communications between server and client subsystems.

Subsystem 102 is shown as a block diagram with many double arrows. These double arrows (no separate reference numerals) represent a communications fabric, which provides communications between various components of subsystem 102. This communications fabric can be implemented with any architecture designed for passing data and/or control information between processors (such as microprocessors, communications and network processors, etc.), system memory, peripheral devices, and any other hardware components within a computer system. For example, the communications fabric can be implemented, at least in part, with one or more buses.

Memory 208 and persistent storage 210 are computer-readable storage media. In general, memory 208 can include any suitable volatile or non-volatile computer-readable storage media. It is further noted that, now and/or in the near future: (i) external device(s) 214 may be able to supply, some or all, memory for subsystem 102; and/or (ii) devices external to subsystem 102 may be able to provide memory for subsystem 102. Both memory 208 and persistent storage 210: (i) store data in a manner that is less transient than a signal in transit; and (ii) store data on a tangible medium (such as magnetic or optical domains). In this embodiment, memory 208 is volatile storage, while persistent storage 210 provides nonvolatile storage. The media used by persistent storage 210 may also be removable. For example, a removable hard drive may be used for persistent storage 210. Other examples include optical and magnetic disks, thumb drives, and smart cards that are inserted into a drive for transfer onto another computer-readable storage medium that is also part of persistent storage 210.

Communications unit 202 provides for communications with other data processing systems or devices external to subsystem 102. In these examples, communications unit 202 includes one or more network interface cards. Communications unit 202 may provide communications through the use of either or both physical and wireless communications links. Any software modules discussed herein may be downloaded to a persistent storage device (such as persistent storage 210) through a communications unit (such as communications unit 202).

I/O interface set 206 allows for input and output of data with other devices that may be connected locally in data communication with server computer 200. For example, I/O interface set 206 provides a connection to external device set 214. External device set 214 will typically include devices such as a keyboard, keypad, a touch screen, and/or some other suitable input device. External device set 214 can also include portable computer-readable storage media such as, for example, thumb drives, portable optical or magnetic disks, and memory cards. Software and data used to practice embodiments of the present invention, for example, program 300, can be stored on such portable computer-readable storage media. I/O interface set 206 also connects in data communication with display 212. Display 212 is a display device that provides a mechanism to display data to a user and may be, for example, a computer monitor or a smart phone display screen.

In this embodiment, program 300 is stored in persistent storage 210 for access and/or execution by one or more computer processors of processor set 204, usually through one or more memories of memory 208. It will be understood by those of skill in the art that program 300 may be stored in a more highly distributed manner during its run time and/or when it is not running. Program 300 may include both machine readable and performable instructions and/or substantive data (that is, the type of data stored in a database). In this particular embodiment, persistent storage 210 includes a magnetic hard disk drive. To name some possible variations, persistent storage 210 may include a solid state hard drive, a semiconductor storage device, read-only memory (ROM), erasable programmable read-only memory (EPROM), flash memory, or any other computer-readable storage media that is capable of storing program instructions or digital information.

The programs described herein are identified based upon the application for which they are implemented in a specific embodiment of the invention. However, it should be appreciated that any particular program nomenclature herein is used merely for convenience, and thus the invention should not be limited to use solely in any specific application identified and/or implied by such nomenclature.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

### II. Example Embodiment

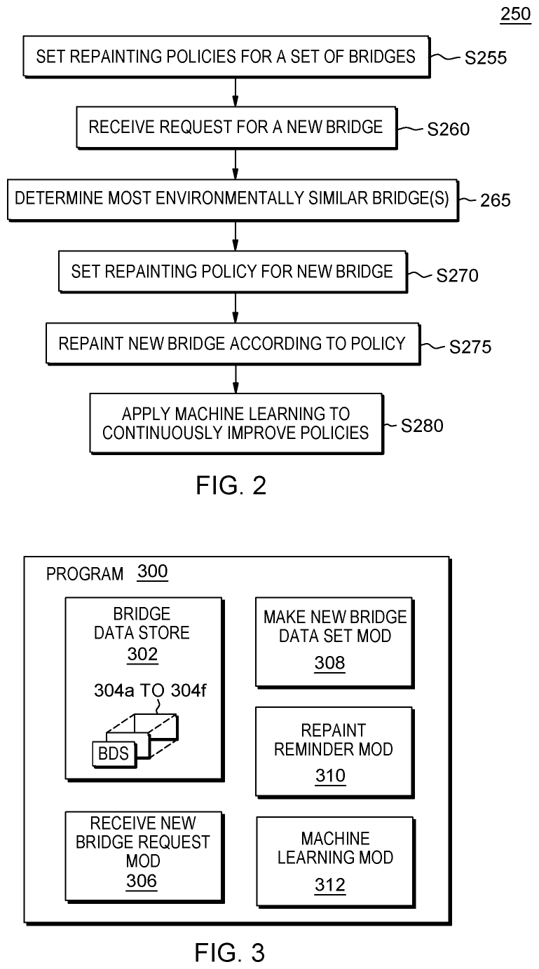

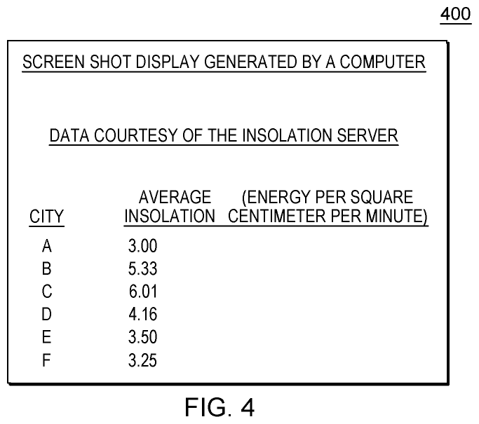

As shown in FIG. 1, networked computers system 100 is an environment in which an example method according to the present invention can be performed. As shown in FIG. 2, flowchart 250 shows an example method according to the present invention. As shown in FIG. 3, program 300 performs or controls performance of at least some of the method operations of flowchart 250. This method and associated software will now be discussed, over the course of the following paragraphs, with extensive reference to the blocks of FIGS. 1, 2 and 3.

Processing begins at operation S255, where bridge data store 302 receives bridge data sets 304a to 304e for five (5) different bridges in five different cities, specifically city A, city B, city C, city D and city E. These data sets 304a to 304e are respectively received from city subsystems 104, 106, 108, 110, 112 and over communication network 114.

Each of the bridge data sets includes the following information about the respectively corresponding bridge: (i) an identification code for the bridge; (ii) the location of the bridge; (iii) the style of bridge structure; (iv) the type of paint used to paint and repaint the bridge; (v) the frequency with which the bridge is repainted as part of bridge maintenance; and (vi) the amount of paint kept in inventory for the bridge when it is not being repainted. The type of paint used to paint and repaint the bridge is sometimes herein referred to as a first environment-related policy because it is an aspect of bridge maintenance that is impacted by the environment in which the respective bridge exists. This relationship between the environment and the bridge repainting schedule will be further discussed below in the subsequent steps of the method of flowchart 250. The amount of paint kept in inventory for the bridge is sometimes herein referred to as a second environment-related policy because it is an aspect of bridge maintenance that is impacted by the environment in which the respective bridge exists. This example uses a bridge as an example of a “physical asset.” Various embodiments of the present invention may be applied to many different types of physical assets, so long as the type of physical asset: (i) has a policy related to its control which is impacted by some aspect of the operating environment (this is sometimes herein referred to as and environmental condition); and (ii) has a relatively fixed geographic location (for example, many motor vehicles are operated within a relatively fixed geographic location).

In this example, the five (5) bridges that are currently being tracked in bridge data store 302 are all considered to be a common type of bridge because they are all painted and repainted with the same type of paint. Physical assets may be grouped into types, of varying degrees of generality, in many different ways including the following: type of object (for example, bridge, building, fire hydrant, motor vehicle); make and model of a type of vehicle (for example, model T Ford brand motor vehicle); and/or type of building (for example, industrial building, apartment building, residential house, retail store, shopping mall, shopping plaza, government building). As will be apparent to those of skill in the art, different types of physical assets can be clustered at many different degrees of granularity and based on many different dimension(s) or parameter(s).

Processing proceeds to operation S260, where receive new bridge request module (“mod”) 306 receives a request to help control maintenance and inventory operations for a new bridge located in city F. This request includes information indicative of the geographic location of the bridge and the type of paint used to paint and repaint the bridge (which is the same type of paint used for the bridges of cities A to E), but it does not include any policy for scheduling repainting of the bridge, and it also does not include any policy with respect to how much paint is regularly kept in inventory for the bridge. It is noted that this new bridge is “new” in the sense that it is just starting to be tracked by server subsystem 102 and program 300, but that doesn't mean that it is a newly constructed bridge—it may be a bridge that has existed for a long time, but does not have a reliable repainting schedule assigned to it as its digital profile comes into data store 302.

It is noted that data sets 304a to 304e would not be considered as digital twins because these data sets don't have any three-dimensional modeling data associated with them. As will be discussed in the next subsection of this Detailed Description section, many embodiments of the present invention may be directed to systems where the digital profiles of the physical assets are in the form of digital twins of the physical assets.

Processing proceeds to operation S265, where make new bridge data set mod 308: (i) determines which environmental conditions are the most relevant to setting a repainting schedule for the bridge in city F; and (ii) determines which of the bridges already reflected in data store 302 that is, bridges in cities A, B, C, D and E, sometimes herein referred to as the Existing Bridges) which is/are the most similar to the bridge and city F with respect to the relevant environmental condition(s); and (iii) sets a repainting policy (that is, the number of years between regularly scheduled repainting some of the bridge) for the new bridge in city F.

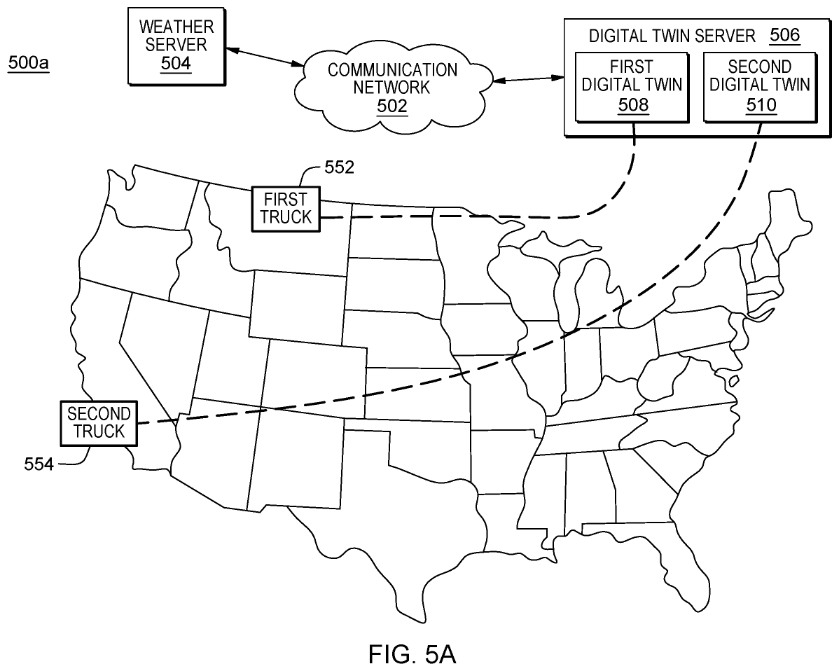

In this example, the Existing Bridges each have a different frequency of repainting that has been set by human individuals based on observations taken over a long period of time. Alternatively, this environment-related policy for repainting could have been set, and/or refined, by a computer in some or all cases. In this example, mod 308 determines that the repainting policies for the Existing Bridges is most closely correlated with the environmental condition amount of incoming solar radiation (that is, insolation) of the city in which the bridges located. In this example, this insolation information is retrieved from insulation server 103 over communication network 114 and is shown in screenshot 400 of FIG. 4.

As shown in screenshot 400, the insolation value for city F is 3.25, which is halfway between the insolation values for city A (specifically, 3.00) and city E (specifically, 3.50). Because these two cities, A and E, are most similar to city F with respect to the relevant environmental condition of insolation, the corresponding data sets 304a and 304e are selected as the existing data sets to use as a basis for setting the repainting policy for new data set 304f that is being constructed by mod 308 for the new bridge in city F. Alternatively, a single data set could be selected. As a further alternative, more than two existing data sets could be selected as the most relevant with respect to the relevant environmental condition(s).

Processing proceeds to operation S270, where mod 308 sets a repainting policy (that is, the number of years between regularly scheduled repainting some of the bridge) for the new bridge in city F based on the repainting schedules already specified for the Existing Bridges in cities A and E. More specifically: (i) bridge of data set 304a, corresponding to city A, instructs that repainting is to occur every 12 years; (ii) bridge of data set 304e, corresponding to city E, instructs that repainting is to occur every 10 years; and (iii) mod 308 makes new data set 304f so that it sets a repainting policy of every 11 years, which is halfway between the policies for data sets 304a and 304e corresponding to the fact that city F experiences a level of insolation that is halfway between city A and city E. Mod 308 also makes other parts of data set 304f, such as setting a paint inventory policy, and stores the completed data set 304f in data store 302 so that the new bridge in city F can start to be tracked, updated and controlled based on data set 304f. As an alternative, data set 304f could be in the form of a digital twin that includes 3D modelling data for the new bridge in city F.

Processing proceeds to operation S275, where repainting reminder mod 310 instructs the workers of the city F, through communication network 114 and city F subsystem 113, to repaint the bridge in city F every eleven years.

Processing proceeds to operation S280, where machine learning mod 312 applies machine learning to continuously improve the substance of the repainting policies for the various bridges tracked by server subsystem 102. In this example, the machine learning machine logic discovers that the amount of rainfall experienced by a bridge is an equally important environmental parameter as compared to the insolation. In response to this, mod 312 refines the repainting policy for data sets 304a to 304f so that it is equally based upon both insolation and rainfall considerations for the geographic locations where the bridges are respectively located.

### III. Further Comments and/or Embodiments

Some embodiments of the present invention recognize the following facts, potential problems and/or potential areas for improvement with respect to the current state of the art: (i) assets that are operated in different regions are affected differently from environmental factors such as weather; and/or (ii) there exists a need for analysis of regional, location, environmental and weather data alongside resources within the digital twin to adjust digital twin resources such as maintenance plans, stocking levels, and forecasted failure rates within the Digital Twin to reflect these environmental factors.

Some embodiments of the present invention may include one, or more, of the following operations, features, characteristics and/or advantages: (i) initiating a digital twin based on the cognitive location and environmental impact of the asset to be operated; (ii) chooses among, and between, a number of digital twins which one is the most appropriate based on where the physical asset is planned to be, or is being, operated; (iii) technically interprets where environmental factors affect digital twin resources; (iv) modifies these digital twin related resources, such as predicted failure rates and maintenance plans for inclusion within enterprise asset management (EAM) solutions; (v) can be tightly integrated with cloud asset management software and/or hardware; (vi) helps to set environmental specific maintenance plans and recommended inventory and spare parts; and/or (vii) using information from similar assets in similar locations, some embodiments can predict and forecast failure rates with higher accuracy.

Some embodiments of the present invention may include one, or more, of the following operations, features, characteristics and/or advantages: (i) a physical asset is associated with a Digital Twin; (ii) over time, the physical asset experiences many location and environmental stresses such as: extreme heat, extreme cold, sudden changes in weather, heavy rains or hail and/or icy roads; (iii) the general operating condition under which a physical asset corresponding to a digital twin runs can affect longevity depending upon parameters such as: temperature, humidity and pollution (air quality); and/or (iv) various actions mandated and/or recommended by operating models reflect the environmental impact (such mandates and/or recommendations may include, for example, changes to spare parts in inventory, parts replaced, maintenance performed and/or system failures.

Some embodiments of the present invention may include one, or more, of the following operations, features, characteristics and/or advantages: (i) the digital twin associated with the physical asset is modified to perform actions recommended and/or mandated by operating models that are based on environmental readings at the time of the entry; (ii) recommended actions can be performed by pulling data from the weather information available online (for example, weather information available through proprietary and/or public APIs); (iii) the Digital Twin associated with the physical asset is modified to reflect adjusted operations along with environmental readings at the time of the entry by pulling data from sensors located on, or in proximity to, on the equipment (for example, sensors that use protocols based on APIs or from building/room sensors); (iv) many digital twins for similar assets may entered into a single asset management system; and/or (v) using cognitive computing and machine learning, over time patterns are uncovered on which adjustments are made to the digital twin for various regions.

An example of a use case of similar assets in the same region (operating conditions) will now be discussed. A new owner/operator of a second physical similar to the first physical asset joins the system. The new owner/operator wishes to initiate a Digital Twin. The new owner/operator specifies the planned location of operation where the second physical asset will be operated. If the system doesn't have a corpus of previous digital twins that reflect the desired location, then: (i) predicted weather data is pulled and compared against other environmentally modified digital twins; (ii) the weather data is compared against the weather data at the already collected corpus of available twins; (iii) on condition that no statistically similar weather patterns are found, a default digital twin is created the user is alerted and asked to pick from options showing variations in weather; and (iv) on condition that a statistically similar weather pattern is found, proceed to the “creation-from-corpus operation” described in the following paragraph.

CREATION-FROM-CORPUS OPERATION: If the system has a corpus of previous digital twins that reflect the same desired location, then the system creates the new digital twin for the second physical asset. Evidence is provided for why changes in Digital Twin resources are suggested based on the operating location. When specific files vary greatly, the system may prompt the second owner/operator to the variations. If, in the future, the physical asset is to be relocated to a new region, the system could do a comparison between the current location weather and the new location weather and any digital twins in both for the asset to recommend augmenting the current digital twin with any environmental specific digital twin changes.

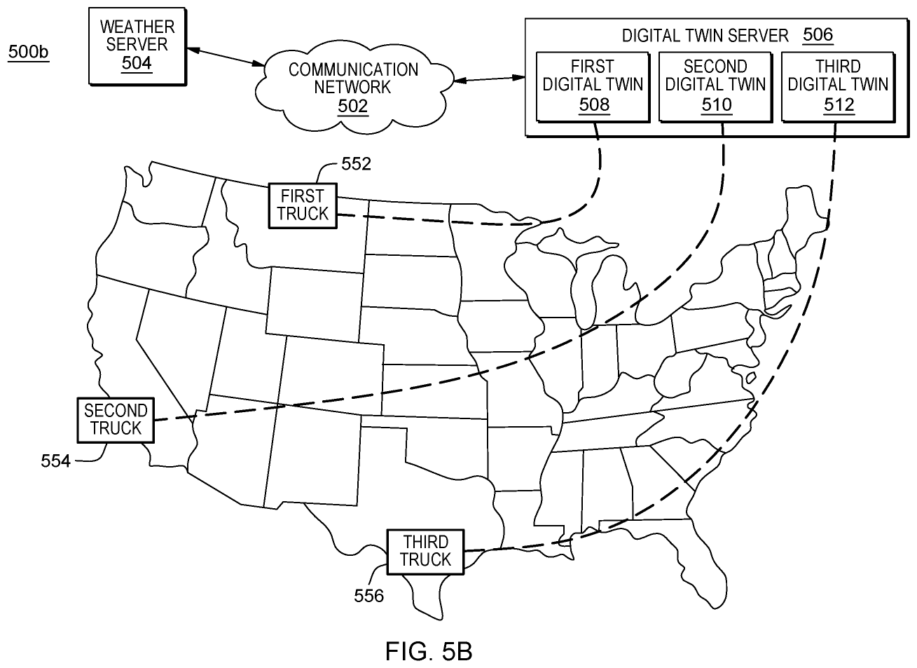

An example of operations according to what is described in the previous two (2) paragraphs will now be discussed with reference to FIG. 5A (showing diagram 500a reflective of a first time T1) and FIG. 5B (showing diagram 500b reflective of a later time T2). As shown in diagram 500a, at time T1, first truck 552 is operated in the state of Montana and second truck 554 is operated in Southern California. A Digital Twin is created for both trucks as follows: (i) first digital twin data set 508, corresponding to first truck 552, is maintained on digital twin server 506; and (ii) second digital twin data set 510, corresponding to second truck 554, is maintained on digital twin server 506. The correspondence between the physical trucks and their respectively corresponding digital twins (DTs) is shown by dashed lines in FIGS. 5A and 5B). Some of the digital twin resources, included in data sets 508 and 510, are the same, such as the operating manual and 3D models. However, each digital twin data set 508, 510 has a unique set of resources as well. The sets of unique resources have been learned over time and include the environmental impact on each digital twin data set (and presumably on the respectively corresponding physical truck). This environmental impact may be reflected in various policies that are included in the digital twin data set, such as policies on frequency of maintenance and number of spare parts in inventory.

In this way, by referring to the digital twin data sets, learning (for example, machine learning) can inform: (i) the impact the environment is having on each truck over time; and (ii) optimal responsive policies (for example, spare parts policies, frequency of maintenance policies) that take the environmental impact into account. At time T1, the policies for first truck 552, as stored in DT data set 508, are as follows: (i) ten (10) spare tires are kept in inventory for first truck 552; (ii) maintenance is once a month during the summer months; and (iii) maintenance is every two (2) months during the winter months. At time T1, the policies for second truck 554, as stored in DT data set 510, are as follows: (i) three (3) spare tires are kept in inventory for second truck 554; and (ii) maintenance is every three (3) months during both summer and winter months. These policies are chosen because tires wear down faster due to road conditions in Montana, relative to Southern California. Trucks in Montana also have to have maintenance performed more frequently, every month in the winter and every two months during the summer months primarily due to harsher weather conditions in Montana, relative to Southern California.

As shown in diagram 500b, at time T2, third truck 556 is purchased and will operate in Texas. Unfortunately, the system doesn't yet have any DTs yet operating in Texas. In response to this, machine logic of DT server 506 does a lookup, from weather server 504 and through communication network 502, of historical and predicted weather for Texas, where third truck 556 will operate. In some embodiments, the look up may include other environmental factors, such as earthquakes, ocean tides, local flora and fauna, local terrain, etc.—anything localized relevant factors that might have an impact on maintenance or inventory policy for a real world resource (for example, a truck). By pulling information from a commercial weather data service provider, a comparison is made between the weather in Texas to the weather for the other DT data sets 508, 510 that already exist on DT server 506. Machine logic of DT server 506 determines that most relevant weather is reflected in second DT data set 510 (the California twin), meaning that DT data set is selected as a default staring state digital twin to use to create third DT data set 512 corresponding to third truck 556. Third DT data set 512 (Texas based) is created based on the resources within second DT data set 510, and not first DT data set 508.

Some additional considerations will now be discussed. A piece of equipment may move from one region to another where the weather conditions are quite different. The operating history of the equipment can be stored in the operating history of the digital twin.

A method, according to an embodiment of the present invention, for generating a digital representation of a physical asset includes the following operations (not necessarily in the following order): (i) receiving a request to initiate a digital representation of a first physical asset; (ii) identifying a geographic location associated with the physical asset; (iii) retrieving weather data for the geographic location from a weather data service via an API; (iv) matching the retrieved weather data to weather data of an existing digital representation of a second physical asset, with the first physical asset and the second physical asset being characterized by a common physical asset type; and v) initiating the digital representation of the first physical asset using the existing digital representation of the second physical asset. The matching operation (iv) includes matching predicted weather data for the geographic location with weather data of the existing digital representation of the second physical asset.

Some embodiments of the present invention may include one, or more, of the following operations, features, characteristics and/or advantages: (i) choosing the best digital twin template to build upon, rather than adjusting the digital twin after operation; (ii) related to the initial creation of the twin; (iii) choosing the corresponding digital twin template or recommendation within the marketplace; (iv) operates within a marketplace setting such as the Digital Twin Exchange; (v) creates a solution during the initial proposal of a digital twin based on environmental factors; (vi) includes technical steps to implement a digital twin within a marketplace setting, in which a number of variations within a digital twin are available and an end user can choose which one to purchase based on the ultimate operating location of the equipment; (vii) once the digital twin template is chosen, the digital twin can evolve over time as that environment changes; (viii) providing a digital twin template to use as the starting point within a marketplace; and/or (ix) doing a comparison and pulling from weather data such as through APIs of a commercial weather data service provider, to determine similar operating environments for those areas that haven't previously collected data to help recommend an initial set of digital twin template(s).

A method according to an embodiment of the present invention performs the following operations (not necessarily in the following order): (i) physical asset is associated with a Digital Twin; (ii) monitoring conditions (specifically “location and environment stresses”) that the physical asset experiences; (iii) generating an operating model to respond to the environmental impact with actions such as changes to spare parts in inventory, parts replaced and maintenance performed; (iv) perform responsive actions on the physical asset based upon the recommendations/mandates of the operating model; (v) the Digital Twin associated with the physical asset is modified to reflect the responsive actions performed in the previous step; (vi) repeat the monitoring of location and environment stresses; (vii) many digital twins for similar assets are entered into the system; and (viii) using cognitive computing and machine learning, over time patterns are uncovered on which adjustments are made to the digital twin for various regions.

In some embodiments, each digital twin includes the following types of digital resources: bill of materials, parts list, user manual(s), engineering manual(s), fault codes, computer aided design files, augmented reality/virtual-reality models, maintenance manuals, maintenance plans, operating model, remote procedures for a technician, stocking strategy, forecast model, building information models (BIM) and service manual.

In some embodiments the physical assets are locationally tracked (for example, by a global positioning system (GPS), and, if it is determined that the first geographic asset has moved to a different operating environment, then a new base PAPDS (for example, base digital twin template) is suggested to replace the existing PAPDS for the re-located physical asset. More specifically, this new base PAPDS is chosen to be suggested based upon between the following: (i) the new operating environment of the relocated physical asset, and (ii) the operating environments of the plurality of existing PAPDSs. Even more specifically, the new suggested base PAPDS is suggested based on environmental similarity (in relevant respects) between the new operating environment of the relocated physical asset and the operating environments of environmentally similar existing PAPDSs.

### IV. Definitions

Present invention: should not be taken as an absolute indication that the subject matter described by the term “present invention” is covered by either the claims as they are filed, or by the claims that may eventually issue after patent prosecution; while the term “present invention” is used to help the reader to get a general feel for which disclosures herein are believed to potentially be new, this understanding, as indicated by use of the term “present invention,” is tentative and provisional and subject to change over the course of patent prosecution as relevant information is developed and as the claims are potentially amended.

Embodiment: see definition of “present invention” above—similar cautions apply to the term “embodiment.”

and/or: inclusive or; for example, A, B “and/or” C means that at least one of A or B or C is true and applicable.

Including/include/includes: unless otherwise explicitly noted, means “including but not necessarily limited to.”

Module/Sub-Module: any set of hardware, firmware and/or software that operatively works to do some kind of function, without regard to whether the module is: (i) in a single local proximity; (ii) distributed over a wide area; (iii) in a single proximity within a larger piece of software code; (iv) located within a single piece of software code; (v) located in a single storage device, memory or medium; (vi) mechanically connected; (vii) electrically connected; and/or (viii) connected in data communication.

Computer: any device with significant data processing and/or machine readable instruction reading capabilities including, but not limited to: desktop computers, mainframe computers, laptop computers, field-programmable gate array (FPGA) based devices, smart phones, personal digital assistants (PDAs), body-mounted or inserted computers, embedded device style computers, application-specific integrated circuit (ASIC) based devices.

Physical asset profile data set (PAPDS): any set of machine readable data that characterizes a physical asset, existing in the “real world,” and includes: (i) information indicative of identity of the physical asset and its type (for example, id code 123 for a given fleet vehicle and an indication that this fleet vehicle is a four door passenger sedan manufactured in 2020), and (ii) a set of digital resources used for operating and/or managing the physical asset in the “real world” (for example, *.pdf file corresponding to an owner's manual corresponding to fleet vehicle 123); at least some “digital twins” (see definition, above, in the Background section) are PAPDS, but not all PAPDS necessarily meet the definition of “digital twin.”

What is claimed is:

1. A computer implemented method (CIM) comprising:
receiving a plurality of existing physical asset profile data sets (PAPDSs), with each existing PAPDS including information indicative of the operating environment in which the existing digital twin is operating;
receiving a request to make a first new PAPDS corresponding to a first physical asset, with the request including information indicative of an operating environment in which the first physical asset is planned to be operated; and
determining a suggested base PAPDS from the plurality of PAPDSs based upon between the following: (i) the operating environments of the suggested base digital twin, and (ii) the operating environment indicated in the request.

2. The CIM of claim 1 further comprising:
communicating an identity of the suggested base PAPDS to a requestor who sent the request.

3. The CIM of claim 2 further comprising:
receiving an instruction, from the requestor, to use the suggested base PAPDS; and
responsive to the instruction, making the first new digital twin using the suggested base PAPDS to supply at least some of the default values for the first new PAPDS.

4. The CIM of claim 3 wherein the first new PAPDS includes at least one of the following types of digital resources: bill of materials, parts list, user manual(s), engineering manual(s), fault codes, computer aided design files, augmented reality/virtual-reality models, maintenance manuals, maintenance plans, operating model, remote procedures for a technician, stocking strategy, forecast model, building information models (BIM) and/or service manual.

5. The CIM of claim 1 wherein:
the plurality of existing PAPDSs are respectively in the form of digital twins;
the first new PAPDS is in the form of a digital twin; and
the request is received through a digital twin marketplace interface.

6. The CIM of claim 1 further comprising:
tracking the location of the first physical asset;
responsive to the tracking, determining that the first geographic asset has moved to a different operating environment; and
responsive to the determination that the first physical asset has moved to a new operating environment, determining a new suggested base PAPDS from the plurality of PAPDSs based upon between the following: (i) the new operating environments of the suggested base digital twin, and (ii) the operating environments of the plurality of existing PAPDSs.

7. A computer program product (CPP) comprising:
a set of storage device(s); and
computer code stored on the set of storage device(s), with the computer code including data and instructions for causing a processor(s) set to perform at least the following operations:
receiving a plurality of existing physical asset profile data sets (PAPDSs), with each existing PAPDS including information indicative of the operating environment in which the existing digital twin is operating,
receiving a request to make a first new PAPDS corresponding to a first physical asset, with the request including information indicative of an operating environment in which the first physical asset is planned to be operated, and
determining a suggested base PAPDS from the plurality of PAPDSs based upon between the following: (i) the operating environments of the suggested base digital twin, and (ii) the operating environment indicated in the request.

8. The CPP of claim 7 wherein the computer code further includes data and instructions for causing the processor set(s) to perform the following operation(s):
communicating an identity of the suggested base PAPDS to a requestor who sent the request.

9. The CPP of claim 8 wherein the computer code further includes data and instructions for causing the processor set(s) to perform the following operation(s):
receiving an instruction, from the requestor, to use the suggested base PAPDS; and
responsive to the instruction, making the first new digital twin using the suggested base PAPDS to supply at least some of the default values for the first new PAPDS.

10. The CPP of claim 9 wherein the first new PAPDS includes at least one of the following types of digital resources: vehicles, bridges, buildings, utility poles, fire hydrants, flood walls, emergency phones, tended gardens, lawns, pumps, large scale electrical components, HVAC (heating, ventilation and air conditioning) components, land, facilities, infrastructure and/or major manufacturing equipment.

11. The CPP of claim 7 wherein:
the plurality of existing PAPDSs are respectively in the form of digital twins;
the first new PAPDS is in the form of a digital twin; and
the request is received through a digital twin marketplace interface.

12. The CPP of claim 7 wherein the computer code further includes data and instructions for causing the processor set(s) to perform the following operation(s):
tracking the location of the first physical asset;
responsive to the tracking, determining that the first geographic asset has moved to a different operating environment; and
responsive to the determination that the first physical asset has moved to a new operating environment, determining a new suggested base PAPDS from the plurality of PAPDSs based upon between the following: (i) the new operating environments of the suggested base digital twin, and (ii) the operating environments of the plurality of existing PAPDSs.

13. The CPP of claim 7 further comprising the processor(s) set, wherein the CPP is in the form of a computer system (CS).

14. A computer-implemented method (CIM) comprising:
receiving a plurality of physical asset data sets for respectively corresponding physical assets having a common asset type, with each given physical asset data set including information indicative of: (i) identity of the respectively corresponding physical asset, (ii) location of the respectively corresponding physical asset, and (iii) a first environment-related policy that controls a first environment-related aspect of handling of the respectively corresponding physical asset;
receiving a new physical asset request including information indicative of (i) identity of a new physical asset, and (ii) location of the new physical asset;
determining a set of relevant environmental condition(s) that are relevant to selection of first-environment related policy for the plurality of first physical assets of the first asset type;
for each given physical asset data set of the plurality of physical asset data sets, determining relevant environmental condition value(s), corresponding to the set of relevant environmental condition(s), under which the physical asset corresponding to the given physical asset data set operates;
for the new physical asset, determining relevant environmental condition value(s), corresponding to the set of relevant environmental condition(s), under which the new physical asset operates; and
creating a new physical asset data set corresponding to the new physical asset, with the creation of the new physical asset data set including:
selecting a selected first environment-related policy to control the first environment-related aspect of handling of the new physical asset based, at least in part upon: (i) the relevant environmental condition value(s) corresponding to the plurality of physical asset data sets, and (ii) the relevant environmental condition value(s) corresponding to the new physical assets, and
adding the selected first environment-related policy to the new physical asset data set.

15. The CIM of claim 14 wherein each physical asset data set of the plurality of physical asset data sets includes at least one of the following types of digital resources: bill of materials, parts list, user manual(s), engineering manual(s), fault codes, computer aided design files, augmented reality/virtual-reality models, maintenance manuals, maintenance plans, operating model, remote procedures for a technician, stocking strategy, forecast model, building information models (BIM) and/or service manual.

16. The CIM of claim 14 further comprising:
receiving operational data relating to the condition and/or operation of at least some of the physical assets respectively corresponding to the plurality of physical asset data sets; and
applying machine learning to the operational data to adjust the first environment-related policy for at least one of the plurality of physical asset data sets.

17. The CIM of claim 14 wherein:
each given physical asset data set, of the plurality of physical asset data sets, is in the form of a digital twin that further includes three dimensional geometry model data for the physical asset corresponding to the given physical asset data set; and
the new physical asset data set is in the form of a digital twin that further includes three dimensional geometry model data for the physical asset corresponding to the given physical asset data set.

18. The CIM of claim 14 wherein the common asset type is at least one of the following asset types: vehicles, bridges, buildings, utility poles, fire hydrants, flood walls, emergency phones, tended gardens, lawns, pumps, large scale electrical components, HVAC (heating, ventilation and air conditioning) components, land, facilities, infrastructure and/or major manufacturing equipment.

19. The CIM of claim 14 wherein each physical asset data further includes information indicative of a maintenance plan.

20. The CIM of claim 14 wherein each physical asset data further includes information indicative of a stocking strategy.
